(19) United States
(12) Patent Application Publication
(10) Pub. No.: US 2020/0292658 A1
(43) Pub. Date: Sep. 17, 2020

(54) METHODS AND APPARATUS FOR DATA COMPRESSION AND TRANSMISSION

(71) Applicant: SEMICONDUCTOR COMPONENTS INDUSTRIES, LLC, Phoenix, AZ (US)

(72) Inventors: Marko MLINAR, Horjul (SI); Simon SROT, Ljubljana (SI)

(73) Assignee: SEMICONDUCTOR COMPONENTS INDUSTRIES, LLC, Phoenix, AZ (US)

(21) Appl. No.: 16/724,448

(22) Filed: Dec. 23, 2019

Related U.S. Application Data
(60) Provisional application No. 62/817,099, filed on Mar. 12, 2019.

(51) Int. Cl. G01S 7/02; G01S 13/02; H03M 7/46; H03M 7/30

(52) U.S. Cl. CPC G01S 7/021; G01S 13/02; H03M 7/70; H03M 7/6011; H03M 7/46

(57) ABSTRACT

Various embodiments of the present technology may comprise methods and apparatus for data compression and transmission. Embodiments the present technology transmit relevant data sub-cubes and compress and transmit non-relevant data sub-cubes. Relevant data sub-cubes may be those sub-cubes that contain detected target data and sub-cubes that are directly adjacent to the detected target data. Data contained in the directly adjacent sub-cubes that are overlapping/shared are only transmitted once.

### CROSS-REFERENCE TO RELATED APPLICATION

This application claims the benefit of U.S. Provisional Patent Application Ser. No. 62/817,099, filed on Mar. 12, 2019, the contents of which are incorporated by reference.

### BACKGROUND OF THE TECHNOLOGY

Processed RADAR data is typically encoded as a multi-dimensional cube of complex numbers and transmitted to a host system. However, storage and transmission of the data cube is associated with significant costs. Therefore, it may be desired to reduce the amount of data transmitted from the data cube without impacting the performance of the system and/or losing information.

### SUMMARY OF THE INVENTION

Various embodiments of the present technology may comprise methods and apparatus for data compression and transmission. Embodiments the present technology transmit relevant data sub-cubes and compress and transmit non-relevant data sub-cubes. Relevant data sub-cubes may be those sub-cubes that contain detected target data and the sub-cubes that are directly adjacent to the detected target data. Data contained in the directly adjacent sub-cubes that are overlapping/shared are only transmitted once.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 is a block diagram of a RADAR system in accordance with an exemplary embodiment of the present technology;

FIG. 2 is a 3-dimensional data cube in accordance with an exemplary embodiment of the present technology;

FIG. 3 is an alternative representation of the 3-D data of FIG. 2 in accordance with an exemplary embodiment of the present technology;

FIG. 4 is an encoded primary data stream in accordance with an exemplary embodiment of the present technology;

FIG. 5 is a supplemental data stream in accordance with an exemplary embodiment of the present technology; and

FIG. 6 is a flow chart for compressing and transmitting data in accordance with an exemplary embodiment of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various filters, transform algorithms, decimators, signal processors, and the like, which may carry out a variety of functions. In addition, the present technology may be practiced in conjunction with any number of systems, such as automotive, aviation, spacecraft, and the systems described are merely exemplary applications for the technology.

Methods and apparatus for data compression and transmission according to various aspects of the present technology may operate in conjunction with any suitable electronic system, such as a RADAR system 100, a LiDAR system, or any other ranging system that processes and compresses data and/or operates on multi-dimensional data.

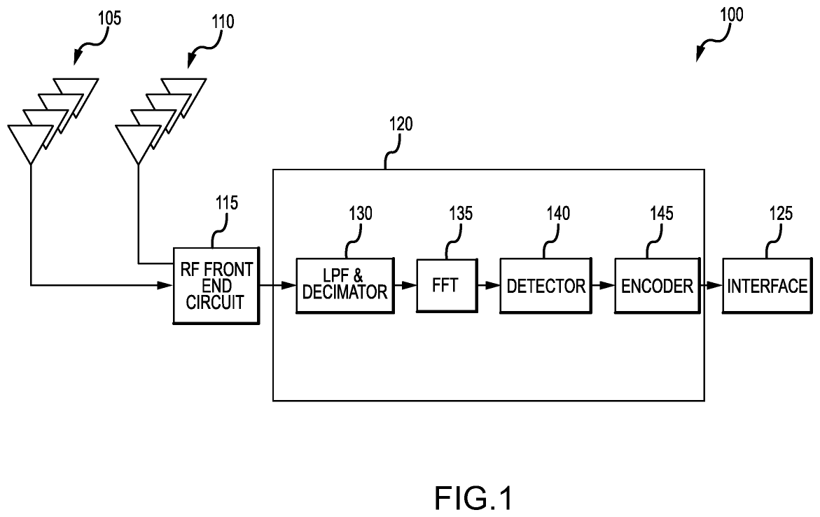

Referring to FIG. 1, the RADAR system 100 according to various aspects of the present technology may be configured to determine range, angle, and velocity of an object using radio waves. In an exemplary embodiment, the RADAR system 100 may comprise a transmitter 110 to transmit a radar signal and a receiver 105 to receive return radar signals reflected from objects in the path of the radar signal. The transmitter 110 and receiver 105 may be configured as a single-in-single-out system or a multiple-in multiple-out system. In addition, the radar system 100 may further comprise a RF front end circuit 115, a RADAR processor 120, and an interface circuit 125 that operate together to process, compress, and transmit return radar data.

The RF front end circuit 115 may receive and process return signals from the receiver 105 at its original radio frequency and generate digital radar data according to the original return signals. For example, the RF front end circuit 115 may comprise any number of multiplexers, filters, mixers, amplifiers, signal converters, and the like. In an exemplary embodiment, the RF front end circuit 115 may transmit the digital radar data to the RADAR processor 120 for additional processing.

The RADAR processor 120 may be configured to process and compress the digital radar data, and generate and transmit an encoded data stream to the interface 125. For example, the RADAR processor 120 may comprise any number of filters, decimators, signal processors, encoders, and the like. In an exemplary embodiment, the RADAR processor 120 may comprise a low pass filter (LPF) and decimator 130, a signal processor 135, a detection circuit 140, and an encoder 145.

The LPF and decimator 130 may be connected to an output of the RF front end circuit 115 to receive the digital radar data. The LPF and decimator 130 may filter the digital radar data and perform decimation on the digital radar data. The LPF and decimator 130 may transmit the processed digital radar data to the signal processor for additional processing. The LPF and decimator 130 may comprise any filter suitable for attenuating undesired high frequencies and passing desired low frequencies and any circuit suitable for downsampling a sequence of samples of the radar data.

The signal processor 135 may be connected to an output of the LPF and decimator 130 to receive the processed digital radar data. The signal processor 135 may perform additional processing on the digital radar data. For example, the signal processor may be configured to perform a Fast Fourier transform (FFT) signal processing function.

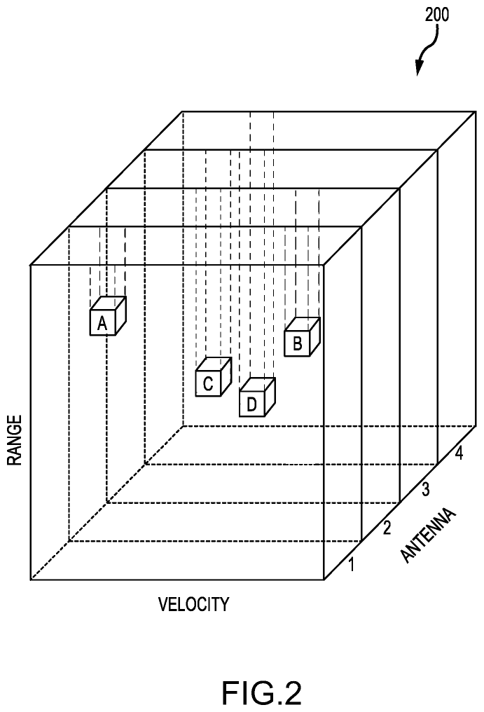

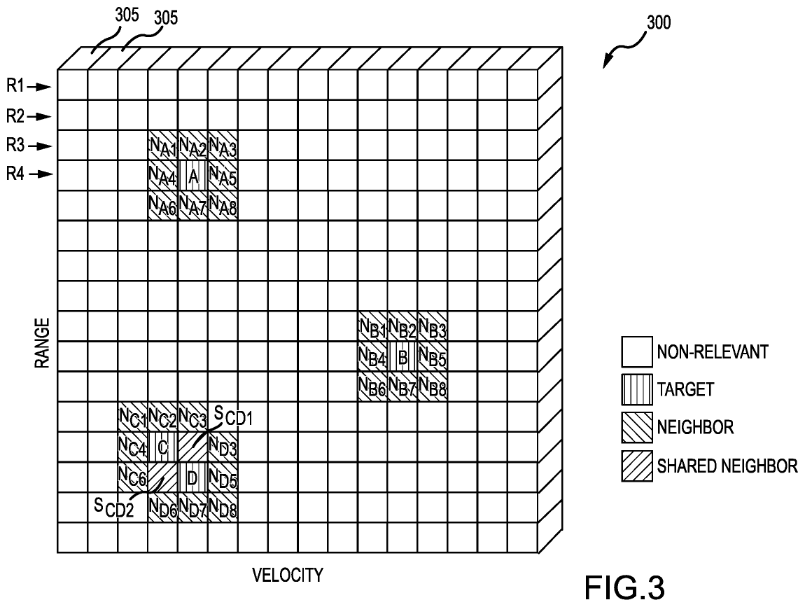

Referring to FIGS. 1-3, the signal processor 135 may be further configured to encode and store the digital radar data as a multi-dimensional data cube (e.g., a 3-dimensional data cube 200), wherein the multi-dimensional data cube may comprise a range dimension, a velocity dimension, and an antenna (angle) dimension. The multi-dimensional data cube may also include an elevation dimension in addition to the range dimension, the velocity dimension, and the antenna dimension.

The multi-dimensional data cube may comprise a plurality of sub-cubes 305, where the location of each sub-cube 305 within the multi-dimensional data cube corresponds to a particular range dimension, velocity dimension, and antenna dimension. Accordingly, the radar data from each return radar signal may be organized within a particular sub-cube 305 according to a range value, a velocity value, and an antenna value of the return radar signal. As such, each sub-cube 305 contains a range value, a velocity value, and an antenna value.

In various embodiments, the 3-dimensional data cube 200 may be treated as a 2-dimensional data array 300 with sub-cubes 305 compressed along the antenna dimension. Accordingly, each sub-cube 305 in the 2-dimensional data array may comprise a range value, a velocity value, and a plurality of antenna values at the given range and velocity.

In various embodiments, the signal processor 135 may comprise a memory (not shown) to store the multi-dimensional data. In other embodiments, however, the signal processor 135 may process, compress, and transmit the multi-dimensional data in a streaming fashion.

The detection circuit 140 may be configured to determine which sub-cubes contain relevant data (referred to as a relevant data sub-cube). In various embodiments, the detection circuit 140 may operate on the 3-dimensional data cube 200, the 2-dimensional data array 300, or any other multi-dimensional data. Relevant data sub-cubes may comprise those sub-cubes 305 that contain target data and those sub-cubes that neighbor (are directly adjacent to) the sub-cubes 305 containing target data.

In an exemplary embodiment, the detection circuit 140 may be configured to identify one or more sub-cubes 305 that contain target data (referred to a “target sub-cube”; e.g., target sub-cubes A, B, C, and D). According to an exemplary embodiment, the detection circuit 140 may compute a power for each sub-cube 305 based on the range value, the velocity value, and the antenna value. The detection circuit 140 may identify the target sub-cube based on the magnitude of the computed power. For example, the detection circuit 140 may compare the power of each sub-cube 305 to a threshold value th. The threshold value th may be predetermined value selected based on the particulars of the ranging system or may be determined by estimating the level of noise in the surrounding sub-cubes of the sub-cube under test. If the power is greater than the threshold value, then the sub-cube 305 is considered to contain target data. In an exemplary embodiment, the detection circuit 140 may implement a conventional constant false-alarm rate detection scheme to determine which sub-cubes contain target data. Alternatively, the detection circuit 140 may comprise a comparator (not shown) to compare the power magnitude to a predetermined threshold.

The detection circuit 140 may be further configured to identify neighboring sub-cubes for each of the detected target sub-cubes. Neighboring sub-cubes may be defined as those sub-cubes that are directly adjacent (left, right, above, below, and diagonally) to a detected target sub-cube. For example, target sub-cube A has neighboring sub-cubes N_{A1}, N_{A2}, N_{A3}, N_{A4}, N_{A5}, N_{A6}, N_{A7}, and N_{A8}, target sub-cube B has neighboring sub-cubes N_{B1}, N_{B2}, N_{B3}, N_{B4}, N_{B5}, N_{B6}, N_{B7}, and N_{B8}, target sub-cube C has neighboring sub-cubes N_{C1}, N_{C2}, N_{C3}, N_{C4}, N_{C5}, S_{CD1}, N_{C6}, and S_{CD2}, and target sub-cube D has neighboring sub-cubes S_{CD1}, N_{D3}, S_{CD2}, N_{D5}, N_{D6}, N_{D7}, and N_{D8}. The detection circuit 140 may be configured to identify neighboring sub-cubes according to their specific location relative to the detected target sub-cubes. The data contained in the neighboring sub-cubes may be referred to as neighbor data.

The detection circuit 140 may be further configured to identify shared neighboring sub-cubes among the neighboring sub-cubes. In some instances, a neighboring sub-cube for one target sub-cube may share the same range value and velocity value with a neighboring sub-cube for different target sub-cube. Accordingly, those neighboring sub-cubes that are shared between at least two target sub-cubes are referred to collectively as the shared neighboring sub-cube. For example, target sub-cube C and target sub-cube D have two shared neighboring sub-cubes (S_{CD1}, S_{CD2}). The data contained in the shared neighboring sub-cubes may be referred to as shared data.

According to an exemplary embodiment, relevant data sub-cubes may comprise those sub-cubes identified as the target sub-cube, the neighboring sub-cube, and the shared neighboring sub-cube. All other remaining sub-cubes (those not identified as the target sub-cube, the neighboring sub-cube, and the shared neighboring sub-cube) may be referred to as non-relevant data sub-cubes.

In various embodiments, the detection circuit 140 may flag or otherwise mark the relevant sub-cubes in a manner that allows the signal processor 135 to identify them as such.

According to an exemplary embodiment, the detection circuit 140 may be connected to an output of the signal processor 135 and configured to receive the multi-dimensional processed radar data from the signal processor. In addition, the detection circuit 140 may transmit the multi-dimensional processed radar data to the encoder 145.

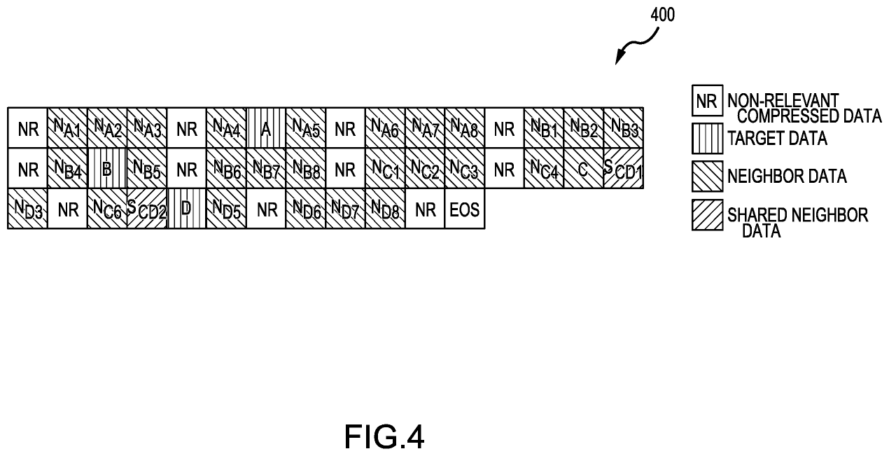

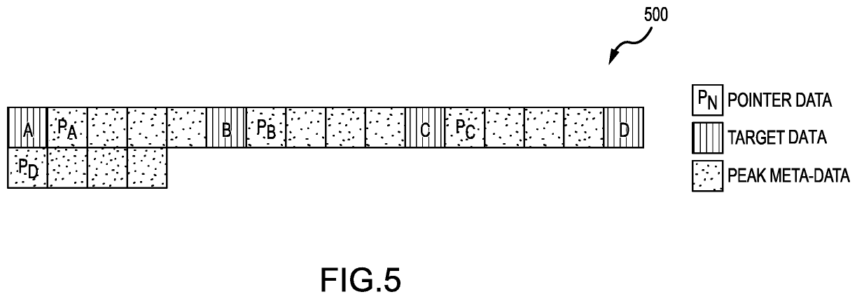

Referring to FIGS. 1-5, the encoder 145 may be configured to compress data and/or generate an encoded data stream. According to an exemplary embodiment, the encoder 145 may receive the multi-dimensional processed radar data from the detection circuit 140 and generate an encoded primary data stream 400 according to the processed radar data.

The encoder 145 may receive the processed radar data with flags indicating the target sub-cubes, the neighboring sub-cubes, and the shared neighboring sub-cubes. The encoder 145 may be configured to transmit the data contained in the relevant data sub-cubes (i.e., the target sub-cubes, the neighboring sub-cubes, and the shared neighboring sub-cubes) and compress non-relevant data sub-cubes. According to an exemplary embodiment, the encoder 145 transmits the data of the shared neighboring sub-cube only once. In other words, the primary data stream 400 contains only one instance of the shared data.

According to an exemplary embodiment, the encoder 145 may be configured to compress a sequence of consecutive non-relevant data sub-cubes into a single, encoded special identifier (symbol). For example, the encoder 145 may perform run-length encoding (RLE) on the processed radar data. The run-length encoding operation may employ a space-filling curve, such as a Hilbert curve, Peano curve, and the like, to select the sequence of consecutive non-relevant data. In various embodiments, the space-filling curve may comprise a 2-dimensional or a 3-dimensional space-filling curve. For example, in the case of the 2-dimensional data array 300, the encoder 145 may encode sub-sets of the non-relevant data using a 2-dimensional space-filling curve. In such a case, rows 1 and 2 (R1 and R2) and the first three sub-cubes in the third row (R3) may be encoded with a first special identifier. Next, the remaining non-relevant sub-cubes of the third row and the first three sub-cubes of the fourth row (R4) may be encoded with a second special identifier, etc, until all of the non-relevant sub-cubes have been encoded.

In a case of a 3-dimensional data cube, the encoder 145 may encode sub-sets of the non-relevant data using a 3-dimensional space-filling curve in a similar manner as the 2-dimensional space-filling curve.

According to an exemplary embodiment, the encoded primary data stream 400 comprises the special identifier and the data from the relevant sub-cubes (i.e. the target data, the neighbor data, and the shared data). The encoded primary data stream may also comprise an end-of-signal (EOS) symbol.

According to an exemplary embodiment, the encoder 145 may also generate a supplemental data stream 500 comprising the target data, and peak meta-data for each target. The peak meta-data may comprise a tuple comprising a peak magnitude value M, the range value r for the respective target, the velocity value v for the respective target, the threshold value th, and a pointer P_{N} (i.e., <r, v, M, th, P_{N}>). The peak meta-data may be output in two or more parallel streams.

The pointer P_{N} may comprise position data that indicates a position in the primary data stream that corresponds to the target data. For example, pointer P_{A} provides the position of the data of target sub-cube A, pointer P_{B} provides the position of the data of target sub-cube B, pointer P_{C} provides the position of the data of target sub-cube C, and pointer P_{D} provides the position of that data of target sub-cube D within the primary data stream. The pointer P_{N} may allow the host device to access antenna values in the same range (to the left or right) of the target data by offsetting the pointer by a desired number. The host device may also use the pointer P_{N} to access data in the sub-cubes above or below the target data sub-cube.

The interface 125 may be configured to transmit the encoded primary data stream 400 and the supplemental data stream 500 to a host device (not shown), such as an advanced driver assist system in an automobile. The interface 125 may be configured as a MIPI (mobile industry processor interface), or any other suitable interface type. The interface 125 may transmit the encoded primary data stream 400 and the supplemental data stream 500 to the host device simultaneously, using two separate virtual channels, or in a serial manner. In various embodiments, the interface 125 may comprise various circuits and/or systems to transmit data in a desired manner, such as a transmitter (not shown), a multiplexer (not shown), a state machine (not shown), a storage device (not shown), and the like.

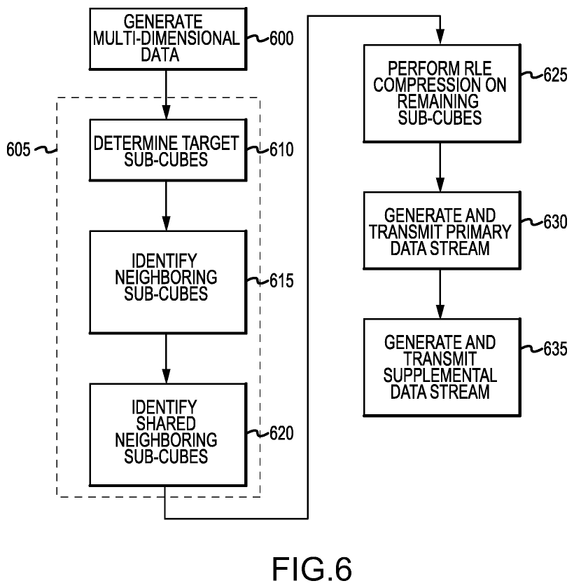

In operation, and referring to FIGS. 1-6, the RADAR system 100 may be configured to encode data. For example, the system 100 may encode radar data from return radar signals. The system 100 may first process the return radar signals. For example, the RF front end circuit 115, the low pass filter and decimator 130, and signal processor 135 may operate together to process the return radar signals and the signal processor may generate and output multi-dimensional processed radar data (600).

The detection circuit 140 may then determine the relevant sub-cubes from the multi-dimensional data (605). According to an exemplary embodiment, determining the relevant sub-cubes comprises determining the target sub-cubes (610), identifying the neighboring sub-cubes (615), and identifying the shared neighboring sub-cubes among the neighboring sub-cubes (620). The detection circuit 140 may compare signals for each sub-cube with a threshold value th to determine if the sub-cube qualifies as a target sub-cube. The detection circuit 140 may identify the neighboring sub-cubes and shared neighboring sub-cubes based on their location relative to the detected target sub-cube. The detection circuit 140 may transmit the multi-dimensional data to the encoder 145.

The encoder 145 may then compress sub-sets of the remaining, non-relevant data (625). For example, the encoder may perform run-length encoding on a sequence of consecutive sub-cubes and encode the sub-set of non-relevant data with the special identifier. The encoder 145 may perform multiple run-length encoding on the non-relevant data and generate multiple special identifiers, one for each compression operation.

The encoder 145 may then generate the primary data stream 400 and transmit the primary data stream 400 to the interface 125 (630). In addition, the encoder 145 may generate the supplemental data stream 500 and transmit the supplemental data stream 500 to the interface 125.

The interface 125 may transmit both the primary data stream 400 and the supplemental data stream 500, either at the same time or one after the other, to the host device.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

1. An apparatus, comprising:
a detection circuit configured to:
receive multi-dimensional data arranged within a plurality of sub-cubes, wherein the plurality of sub-cubes comprises:
a plurality of relevant sub-cubes comprising relevant data; and
a plurality of non-relevant sub-cubes comprising non-relevant data; and
determine the plurality of relevant sub-cubes comprising relevant data, from the plurality of sub-cubes, comprising:
detecting a plurality of target sub-cubes among the plurality of sub-cubes;
identifying neighboring sub-cubes for each detected target sub-cube; and
identifying a shared neighboring sub-cube among the neighboring sub-cubes; and
an encoder connected to the detection circuit and configured to:
encode non-relevant data from the plurality of non-relevant sub-cubes; and
generate a primary data stream comprising the relevant data from the relevant sub-cubes and the encoded non-relevant data.

2. The apparatus according to claim 1, wherein the primary data stream comprises only one instance of data from the shared neighboring sub-cube.

3. The apparatus according to claim 1, wherein the encoder encodes the data from the non-relevant sub-cubes with a special identifier using run-length encoding.

4. The apparatus according to claim 1, wherein the encoder encodes the data from the non-relevant sub-cubes according to a space-filling curve.

5. The apparatus according to claim 1, wherein the encoder is further configured to generate a supplemental data stream comprising the data from the detected target sub-cubes and peak meta-data for each detected target sub-cube.

6. The apparatus according to claim 5, wherein the peak meta-data is a tuple comprising a peak magnitude value, a range value, a velocity value, a threshold value, and a pointer for a respective detected target sub-cube.

7. The apparatus according to claim 6, wherein each pointer indicates a location of a respective detected target sub-cube within the primary data stream.

8. The apparatus according to claim 1, wherein data of each sub-cube comprises at least one of: a range value, a velocity value, and an antenna value.

9. A method for encoding data, comprising:
arranging multi-dimensional data within a plurality of data sub-cubes;
determining relevant data from the plurality of data sub-cubes;
encoding non-relevant data, from the plurality of data sub-cubes, using a single, special identifier; and
generating a primary data stream comprising transmitting the relevant data and the special identifier.

10. The method according to claim 9, wherein determining the relevant data comprises:
detecting a plurality of target sub-cubes among the plurality of data sub-cubes;
identifying neighboring sub-cubes for each detected target sub-cube; and
identifying a shared neighboring sub-cube among the neighboring sub-cubes.

11. The method according to claim 10, wherein transmitting the relevant data comprises transmitting data from the shared neighboring sub-cube only once.

12. The method according to claim 9, further comprising generating a supplemental data stream comprising the data from the detected target sub-cubes and peak meta-data for each detected target sub-cube.

13. The method according to claim 12, wherein the peak meta-data is a tuple comprising a peak magnitude value, a range value, a velocity value, a threshold value, and a pointer for a respective detected target sub-cube.

14. The method according to claim 13, wherein the pointer indicates a location of data from a respective detected target sub-cube within the primary data stream.

15. The method according to claim 9, further comprising selecting a sub-set of non-relevant data sub-cubes according to a space-filling curve.

16. A system, comprising:
a data processor configured to generate multi-dimensional data arranged within a plurality of sub-cubes, wherein each sub-cube comprises data from the multi-dimensional; wherein the data processor comprises:
a detection circuit configured to determine relevant sub-cubes, from the plurality of sub-cubes, based on a magnitude of the data; and
an encoder connected to the detection circuit and configured to:
encode data from non-relevant sub-cubes, from the plurality of sub-cubes, comprising compressing the data from the non-relevant sub-cubes into a single, special identifier;
generate a primary data stream comprising data from the relevant sub-cubes and the special identifier; and
generate a supplemental data stream comprising data from the relevant sub-cubes and meta-data; and
an interface connected to the data processor and configured to transmit the primary data stream and the supplemental data stream to a host device.

17. The system according to claim 16, wherein determining the relevant sub-cubes comprises:
detecting a plurality of target sub-cubes among the plurality of sub-cubes;
identifying neighboring sub-cubes for each detected target sub-cube; and
identifying a shared neighboring sub-cube among the neighboring sub-cubes.

18. The system according to claim 16, wherein the encoder encodes data from the non-relevant sub-cubes according to a space-filling curve.

19. The system according to claim 16, wherein the primary data stream comprises only one instance of the data from the shared neighboring sub-cube.

20. The system according to claim 16, wherein the data for each sub-cubes comprises at least one of: a range value, a velocity value, and an antenna value.
